(19) United States
(12) Patent Application Publication
(10) Pub. No.: US 2009/0168550 A1
(43) Pub. Date: Jul. 2, 2009

(54) Output port, microcomputer and data output method

(75) Inventor: Kaori Oba, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/318,105

(22) Filed: Dec. 22, 2008

(30) Foreign Application Priority Data
Dec. 28, 2007 (JP) 2007-339133

(51) Int. Cl. G11C 7/00; G11C 8/18

(52) U.S. Cl. 365/189.05; 365/189.011; 365/233.1

(57) ABSTRACT

An output port circuit includes a plurality of output buffers; a plurality of first holding circuits configured to hold output data to be outputted to the plurality of output buffers; a plurality of second holding circuits configured to hold output data to be outputted to the plurality of first holding circuits; and a plurality of third holding circuits configured to hold bit pattern data for individually setting whether the output data of the plurality of second holding circuits are latched by the plurality of first holding circuits. Data input to the plurality of second holding circuits and data input to the plurality of third holding circuits are controlled at a same timing.

### INCORPORATION BY REFERENCE

This patent application claims a priority on convention based on Japanese Patent Application 2007-339133. The disclosure thereof is incorporated herein by reference.

### BACKGROUND OF THE INVENTION

1. Field of the Invention

The present invention relates to an output port circuit which changes a data in units of bits, a microcomputer having the output port and a data outputting method.

2. Description of Related Art

FIG. 1 shows a configuration of an output circuit disclosed in Japanese Patent No. 2890660. This output circuit is provided with a bit selection type output port 50. The bit selection type output port 50 includes holding circuits 52 and 54 to be controlled by a CPU 40, and a selecting circuit 53 into which a data signal of a data bus is supplied. The holding circuit 52 holds a bit pattern signal (to be referred to as a mask pattern signal, hereinafter) sent from the CPU 40 to output as a bit selection instruction signal. The selecting circuit 53 selects a data from the data bus 51 to a bit instructed by the bit selection instruction signal and selects a data held in the holding circuit 54 to a bit which is not instructed by the bit selection signal, and outputs the selected data to the holding circuit 54. The holding circuit 54 holds a data outputted from the selecting circuit 53 to output as an output data signal in accordance with a control signal sent from the CPU 40.

According to the bit selection type output port 50, the CPU 40 transmits to the data bus 51, a mask pattern signal specifying a bit desired to change and a data signal which is written into the bit, and changes the data in units of bits.

In the bit selection type output port, writing a mask pattern into the holding circuit 52 and writing data into the holding circuit 53 are carried out at different timings by instructions from control signal lines 55 and 56. Accordingly, there is a risk that an interrupt command is issued between a command for writing a mask pattern and a command for writing a data corresponding to the mask pattern. In such a case, a mask pattern which differs from a mask pattern written prior to the interruption is written in an interrupt process. Therefore, mismatching between a mask pattern desired by the CPU and a data to be written is caused, so that a bit desired to be changed may be left unchanged and a bit desired to be unchanged may be changed.

As an example, a case will be described in which output terminals of the output port has a 4-bit configuration, the CPU 40 masks bits 1 to 3, and a data is written into the holding circuit 53. If no interrupt command is issued, only the bit 0 of the data held by the holding circuit 53 is rewritten. However, if an interrupt command is issued after a mask pattern for masking the bits 1 to 3 in the holding circuit 52 is written, only the bit 1 is rewritten but the bit 0 is maintained in the holding circuit 53 after the interruption, because of the mask pattern changed by an interruption process (e.g. mask pattern for masking the bits 0 to 2). In the output port according to a conventional technique, there is a case that a data with the bit as a rewrite target is not rewritten if an interrupt command is issued between a process to write the mask pattern and a process to write the data.

For this reason, in the bit selecting port according to the conventional technique, it is necessary to inhibit generation of an interrupt command by programming (or in software) such that the interrupt command is not generated between a command to write a mask pattern into the holding circuit 14 and a command to write the data into the holding circuit 53.

Meanwhile, in an application filed using a microcomputer of a single chip (to be referred to as a 1-chip microcomputer, hereinafter), it is required to realize quality improvement even if a software size is significantly enlarged. In the development of the 1-chip microcomputer using a conventional bit selection type port, software development needs to be carried out while considering presence or absence of the interruption. For this purpose, it is necessary to add an interruption prohibiting command for every bit operation command, resulting in an increased program size. In case of changing hardware, software also needs to be changed significantly, which increases a burden to develop large-scale software.

### SUMMARY

In an aspect of the present invention, an output port circuit includes: a plurality of output buffers; a plurality of first holding circuits configured to hold output data to be outputted to the plurality of output buffers; a plurality of second holding circuits configured to hold output data to be outputted to the plurality of first holding circuits; and a plurality of third holding circuits configured to hold bit pattern data for individually setting whether the output data of the plurality of second holding circuits are latched by the plurality of first holding circuits. Data input to the plurality of second holding circuits and data input to the plurality of third holding circuits are controlled at a same timing.

In another aspect of the present invention, a microcomputer includes an output port circuit, a data bus, a memory and an operation processing circuit. The output port circuit includes: a plurality of output buffers, a plurality of first holding circuits configured to hold output data to be outputted to the plurality of output buffers, a plurality of second holding circuits configured to hold output data to be outputted to the plurality of first holding circuits, and a plurality of third holding circuits configured to hold bit pattern data for individually setting whether the output data of the plurality of second holding circuits are latched by the plurality of first holding circuits. Data input to the plurality of second holding circuits and data input to the plurality of third holding circuits are controlled at a same timing. The data bus is connected with the output port circuit. The operation processing circuit is configured to output a write signal based on an instruction code stored in the memory. The operation processing circuit outputs data on the data bus, and the output port circuit holds the data on the data bus in response to the write signal to output to an external unit.

In still another aspect of the present invention, a data outputting method includes: a plurality of second holding circuits latching and holding output data to be outputted to a plurality of first holding circuits; a plurality of third holding circuits latching and holding bit pattern data for individually setting whether the output data of the plurality of second holding circuits are latched by a plurality of first holding circuits, at a same timing as the plurality of second holding circuits; and a plurality of first holding circuits holding output data to be outputted to a plurality of output buffers. The plurality of output buffers outputs output data held by the plurality of first holding circuits.

A port circuit, a microcomputer and a data output method according to the present invention allow to switch an output data in units of bits without having effects of an interrupt process.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a circuit diagram showing a configuration of a conventional output circuit;

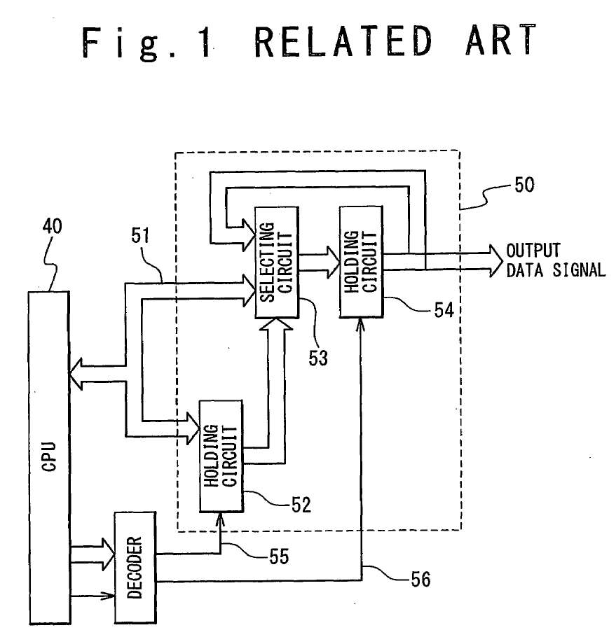

FIG. 2 is a block diagram showing a configuration of a microcomputer according to the present invention;

FIG. 3 is a circuit diagram showing a configuration of a port circuit according to a first embodiment of the present invention;

FIG. 4 is a block diagram showing a configuration of a control circuit provided in the port circuit according to the present invention;

FIGS. 5A to 5F are timing charts showing an operation of the port circuit according to the first embodiment of the present invention;

FIG. 6 is a circuit diagram showing a configuration of the port circuit according to a second embodiment of the present invention; and

FIGS. 7A to 7G are timing charts showing an operation of the port circuit according to the second embodiment of the present invention.

### DESCRIPTION OF THE PREFERRED EMBODIMENTS

Hereinafter, a microcomputer with an output port of the present invention will be described below with reference to the attached diagrams. The same or similar reference numbers are assigned to the same or similar components in the drawings.

### (General Configuration of Microcomputer)

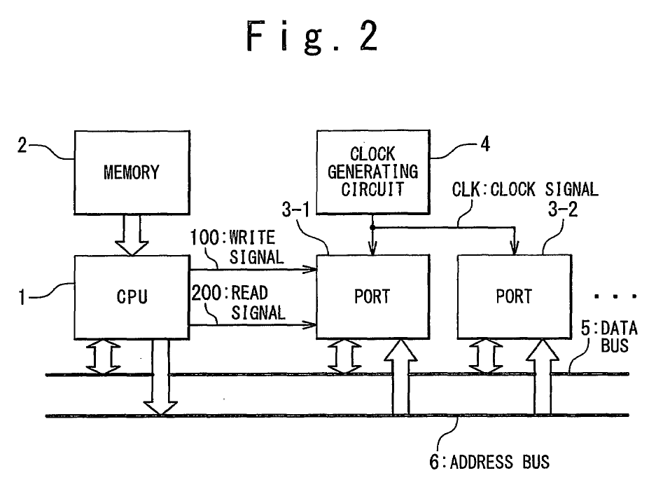

FIG. 2 shows a configuration of a microcomputer according to the present invention. The microcomputer according to the present invention includes a CPU 1, a memory 2, a plurality of port circuits 3-1, 3-2 . . . (to be collectively referred to as a port circuit 3, hereinafter), a clock generating circuit 4, a data bus 5 and an address bus 6. The CPU 1 reads a program code stored in the memory 2, and outputs a write signal 100 and a read signal 200 to the port circuit 3 on the basis of the program code. When outputting a calculation result and data stored in the memory to an external unit (not shown), the CPU 1 uses the address bus 6 to access the port circuit 3 and outputs the data to the port circuit 3 via the data bus 5. At this time, the CPU 1 outputs the write signal 100 to the port circuit 3 to instruct data output. When receiving a data from the external unit (not shown) via the port circuit 3, the CPU 1 also outputs the read signal 200 to the port circuit 3 to instruct data read. At this time, the CPU 1 uses the address bus 6 to access the port circuit 3 and receives the data read via the data bus 5 in accordance with the read signal 200.

The port circuit 3 controls the data input/output between the data bus 5 and the external unit (not shown) in accordance with the write signal 100 and the read signal 200. At this time, the port circuit 3 executes a process to receive a data from the data bus 5 and a process to a data onto the data bus 5 at timings determined based on a clock signal CLK supplied from the clock generating circuit 4.

### First Embodiment

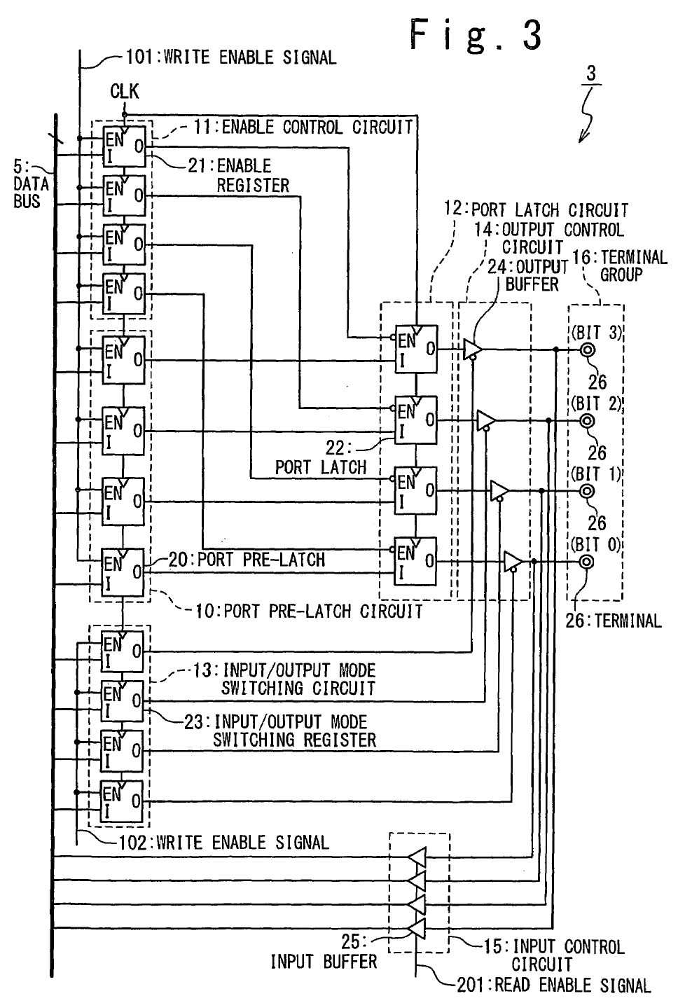

FIG. 3 is a circuit diagram showing a configuration of the port circuit 3 according to a first embodiment of the present invention. In the following embodiments, an example will be described in which the port circuit 3 controls input/output of 4-bit data.

The port circuit 3 includes a port pre-latch circuit 10, an enable control circuit 11, a port latch circuit 12, an input/output mode switching circuit 13, an output control circuit 14, an input control circuit 15 and a terminal group 16. A same clock signal CLK is supplied to the port pre-latch circuit 10, the enable control circuit 11, the port latch circuit 12 and the input/output mode switching circuit 13 so as to operate in accordance with the clock signal CLK. Also, the terminal group 16 has a plurality of terminals 26, e.g. four terminals 26 corresponding to bits 0 to 3 in this example.

The port pre-latch circuit 10 is provided with a plurality of port pre-latches 20 corresponding to the number of terminals. In this example, the port pre-latch circuit 10 is provided with four port pre-latches 20 corresponding to the bits 0 to 3. The port pre-latch circuit 10 holds data on predetermined bit positions (i.e. signal lines) of the data bus 5 in response to a write enable signal 101. The port pre-latch circuit 10 is enabled during a period of the write enable signal 101 in a high level, and extracts and holds data of the data bus 5 in synchronization with the clock signal CLK. The data held by the port pre-latch circuit 10 is outputted to the port latch circuit 12 (i.e. outputted to the terminal group 16). If the data bus 5 has the bus width of 8 bits, the CPU 1 outputs data including a change data to a lower 4-bit portion of the data bus 5, and the port pre-latch circuit 10 extracts and hold the data on the lower 4-bit portion of the data bus 5.

The enable control circuit 11 is provided with a plurality of enable registers 21 corresponding to the number of the terminals. In this example, the enable control circuit 11 is provided with four enable register 21 corresponding to the bits 0 to 3. The enable register circuit 11 holds data on predetermined bit positions (i.e. signal lines) of the data bus 5 in response to the write enable signal 101. The enable control circuit 11 is enabled during a period of the write enable signal 101 in the high level, and extracts and holds data on the data bus 5 in synchronization with the clock signal CLK. The data held by the enable register circuit 11 are a bit pattern data (i.e. a mask pattern data) to determine a bit of the data to be changed. If the data bus 5 has a bus width of 8 bits, the CPU 1 outputs the mask data onto an upper 4-bit portion of the data bus 5, and the enable control circuit 11 holds the data on the upper 4-bit portion of the data bus 5.

The port pre-latch circuit 10 and the enable control circuit 11 latch data based on the same write enable signal 101 in synchronization with the same clock signal CLK, so that data of the data bus 5 is received at the same timing. In order to latch different data (i.e. change data and mask data) by the port pre-latch circuit 10 and the enable control circuit 11 at the same time, it is preferable to latch data from different bit positions (i.e. signal lines) on the data bus 5. Accordingly, in order to realize the port circuit 3 of four bits, the data bus 5 is required to have the bus width of a total of eight bits of four bits for the change data and four bits for the mask data at least.

The port latch circuit 12 is provided with a plurality of port latches 22 corresponding to the number of terminals. In this example, the port latch circuit 12 is provided with four port latches 22 corresponding to the bits 0 to 3. An input of the port latch 22 is connected to an output of a corresponding port pre-latch 20. An output of the port latch 22 is also connected to a corresponding terminal 26 via an output buffer 24. The port latch 22 latches and holds an output data of the corresponding port pre-latch 20 in accordance with an output of the corresponding enable register 21. If the output of the enable register 21 is in the low level of “0”, the port latch 22 is enabled to latch the output of the port pre-latch 20 in response to the clock signal CLK. In contrast, if the output of the enable register 21 is in the high level of “1”, the port latch 22 is disabled to maintain the latched data. The port latch 22 into which data can be written is specified in the port latch circuit 12 based on the mask data held by the enable control circuit 11, and data held by the port pre-latch 20 which is connected to the writable port latch 22 is supplied to the port latch 22 so that the data change can be realized in units of bits.

By the configuration as described above, only the port latches 22 which are specified based on the mask data can latch the data held by the corresponding port pre-latches 20 in the port circuit 3 according to the present embodiment. Thus, the output data from the port circuit 3 can be changed in units of bits.

The input/output mode switching circuit 13 is provided with a plurality of input/output mode switching registers 23 corresponding to the number of terminals. In this example, the input/output mode switching circuit 13 is provided with four input/output mode switching registers 23 corresponding to the bits 0 to 3. The input/output mode switching circuit 13 holds data on predetermined bit positions (i.e. signal lines) of the data bus 5 in accordance with a write enable signal 102. If the write enable signal 102 in the high level is supplied, the input/output mode switching circuit 13 is enabled and extracts and holds data from the data bus 5 in synchronization with the clock signal CLK. The output of the input/output mode switching register 23 is used to control the corresponding output buffers 24 and set the corresponding output buffer 24 to either an ON-state or a high-impedance state. The input/output mode switching registers 23 sets the output buffers 24 to an ON-state in an output mode, and sets them to a high-impedance state in an input mode.

The output control circuit 14 is provided with the output buffers 24 corresponding to the number of terminals. In this example, the output control circuit 14 is provided with four output buffers 24 corresponding to the bits 0 to 3. Preferably, a tri-state buffer is used as the output buffer 24. In the output mode, the output control circuit 14 outputs data held by the port latch circuit 12 to the terminal group 16 as the output data in accordance with the output from the input/output mode switching circuit 13.

The input control circuit 15 is provided with a plurality of input buffers 25 corresponding to the number of terminals. In this example, the input control circuit 15 is provided with four input buffers 25 corresponding to the bits 0 to 3. Preferably, a tri-state buffer is used as the input buffer 25 which is turned on or set to a high-impedance state in accordance with a read enable signal 201. The input buffer 25 is set to an ON-state in the input mode to transfer a data from the terminals 26 to the data bus 5, while being set to a high-impedance state in the output mode.

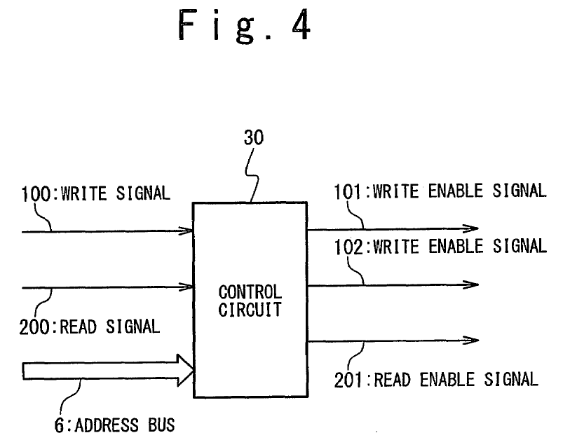

The port circuit 3 according to the first embodiment is further provided with a control circuit 30 as shown in FIG. 4. The control circuit 30 according to the first embodiment outputs the write enable signal 101 and the write enable signal 102 based on the write signal 100 and an address signal on the address bus 6. It is preferable here that the port pre-latch circuit 10 and the enable control circuit 11 are set to have an identical address. Therefore, it is possible for the control circuit 30 to output the write enable signal 101 to the port pre-latch circuit 10 and the enable control circuit 11 at the same timing. The control circuit 30 also outputs the read enable signal 201 on the basis of the read signal 200 and the address signal on the address bus 6.

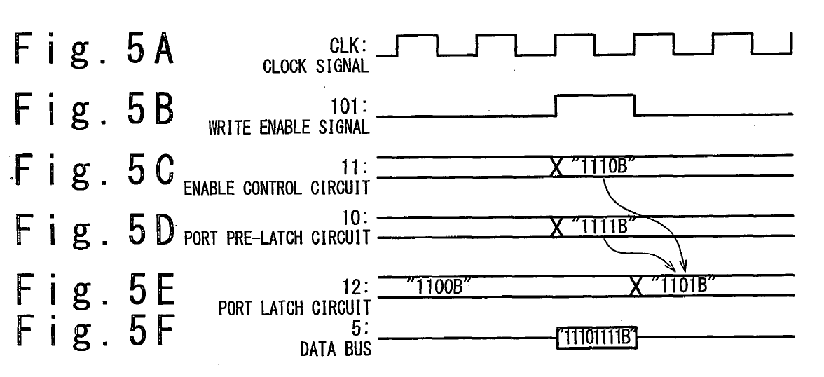

Next, an operation of the port circuit 3 according to the first embodiment of the present invention will be described below with reference to timing charts shown in FIGS. 5A to 5F. The operation will be described in case that the port latch circuit 12 initially holds data “1100B” and the data of the bit 0 is changed to “1” on the terminal group 16.

In order to change data of the bit 0 to “1”, the CPU 1 outputs “1110” corresponding to a mask pattern data to the upper bit portion of the data bus 5, and “1111” to the lower bit portion, and outputs the write signal 100. Thus, the data “11101111B” is outputted onto the data bus 5. A change data may be any data as long as the bit 0 takes “1”, and “0001” may be used. However, it is preferable to set the change data to “1111” if the data is changed to “1”, and set the change data to “0000” if the data is changed to “0”, since the change of data on another bit position becomes possible (including a case of change of data on a plurality of bits positions). It is therefore possible to change the data in units of bits without requiring a complicated setting.

When the write signal 100 is outputted from the CPU 1, the control circuit 30 outputs the write enable signal 101 to the port pre-latch circuit 10 and the enable control circuit 11. The data on the data bus 5 is supplied to the port pre-latch circuit 10 and the enable control circuit 11 during a period of the write enable signal 101 in the high level in response to the clock signal CLK. The data “1111B” of the lower 4-bit portion on the data bus 5 is supplied to the port pre-latch circuit 10, while the data “1110B” of the upper 4-bit portion on the data bus 5 is supplied to the enable control circuit 11.

The port latch circuit 12 latches the data from the port pre-latch circuit 10 in synchronization with a clock of the clock signal subsequent to the clock when the data was latched in the port pre-latch circuit 10 and the enable control circuit 11. The mask pattern data “1110” written in the enable control circuit 11 is used to allow only the port latch 22 corresponding to the bit 0 to latch the data “1” from the corresponding port pre-latch 20. The remaining port latches 22 maintain the previous data. Accordingly, the data held by the port latch circuit 12 is changed from “1100” to “1101”. The data “1101” held by the port latch circuit 12 is outputted to the terminal group 16 via the output control circuit 14.

As described above, the mask pattern data is supplied at the same timing as the change data, in the port circuit 3 according to the present invention. Therefore, the mask pattern data indicating change bit positions and the change data are both supplied to the port latch circuit 12 without breaking a corresponding relation therebetween. Thus, consistency is maintained between a first holding circuit which is enabled to latch a data and the write data, whereby an error caused by an interrupt process can be prevented. Accordingly, the port circuit 3 according to the present invention makes it possible to change the output data in units of bits without receiving effects of the interruption.

Furthermore, the port circuit 3 according to the present embodiment does not require a selection circuit, unlike the conventional port circuit, and it is possible to reduce a circuit area.

### Second Embodiment

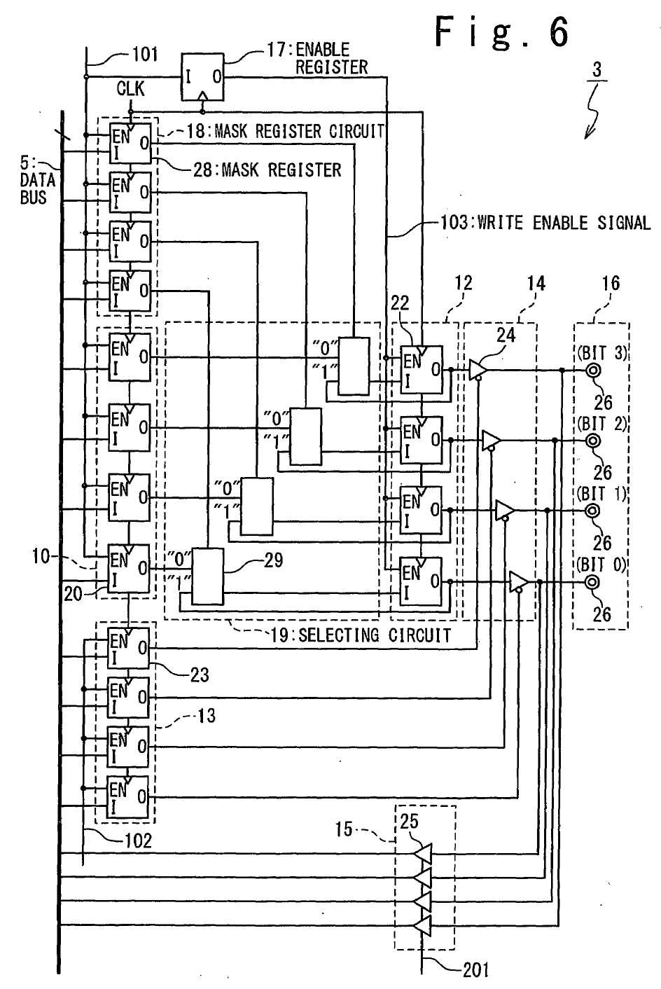

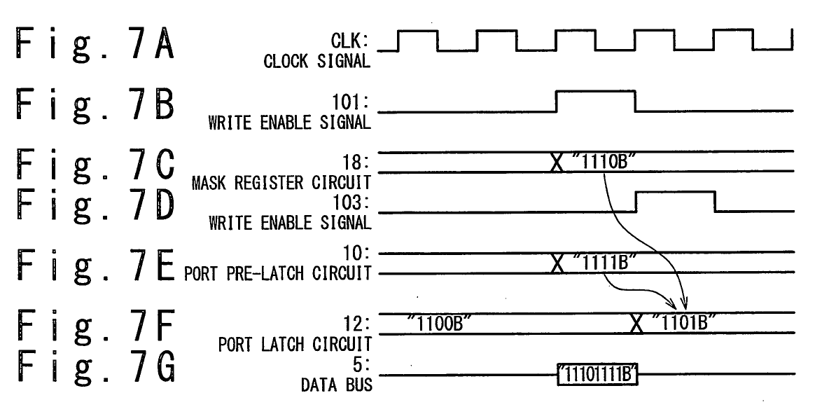

Next, the configuration and operation of the port circuit 3 according to a second embodiment of the present invention will be described in detail with reference to FIG. 6 and FIGS. 7A to 7G. FIG. 6 shows the configuration of the port circuit 3 according to the second embodiment of the present invention. In the following description, the description of the same configuration and operation of the port circuit 3 in the second embodiment as those of the port circuit in the first embodiment is omitted, and only the different portion in the configuration and operation will be described.

Referring to FIG. 6, the port circuit 3 according to the second embodiment includes an enable register 17, a mask register circuit 18 and a selecting circuit 19 in place of the enable control circuit 11 in the first embodiment. In the port circuit 3 of the second embodiment, effects by the interrupt command are eliminated without a significant change to the configuration of the conventional port circuit using the selecting circuit.

The enable register 17 outputs a write enable signal 103 to the port latch circuit 12 in accordance with the write enable signal 101, to control the port latches 22 to be set to an enabled state or a disabled state. The enable register 17 outputs the write enable signal 103 in the high level during a period of the write enable signal 101 in the high level in synchronization with the clock signal CLK.

The mask register circuit 18 is provided with mask registers 28 corresponding to the number of the terminals. In this example, the mask register circuit 18 is provided with four mask registers 28 corresponding to the bits 0 to 3. The mask register circuit 18 holds a data of predetermined bit portions of the data bus 5 in accordance with the write enable signal 101. The mask register circuit 18 is enabled to extract and hold the data on the data bus 5 during a period of the write enable signal 101 in the high level in synchronization with the clock signal CLK. The data held by the mask register circuit 18 is the mask pattern data to determine a bit position of the change data. If the data bus 5 has the bus width of 8 bits, the CPU 1 outputs the mask pattern data to the upper 4-bit portion of the data bus 5 and the mask register circuit 18 holds the data of the upper 4-bit portion of the data bus 5. An output of the mask register 28 is connected to a corresponding selector 29 of the selecting circuit 19 to control a selection operation of the selecting circuits 29.

The selecting circuit 19 is provided with a plurality of the selecting circuits 29 in correspondence with the number of terminals. In this example, the selecting circuit 19 is provided with four selectors 29 corresponding to the bits 0 to 3. The inputs of the selector 29 are connected to an output of the corresponding port pre-latch 20 and an output of the corresponding port latch 22. The selector 29 selects either the output of the port pre-latch 20 or the output of the port latch 22 in accordance with the output from the corresponding mask register 28 to output to the port latch 22. For example, the selector 29 selects the output of the port pre-latch 20 to output to the port latch 22 when the output of the mask register 28 is in the low level of “0”, whereas the selector 29 select the output of 5 the port latch 20 to output to the port latch 22 when the output of the mask register 28 is in the high level of “1”. That is, the selecting circuit 19 outputs the change data latched by the port pre-latch circuit 10 to the port latch circuit 12 on the basis 10 of the mask pattern data latched by the mask register circuit 18.

The port latch 22 in the second embodiment latches and holds the data outputted from the corresponding selector 29 in accordance with the write 15 enable signal 103. If the write enable signal 103 is in the high level, the port latch 22 is enabled to latch the output of the selector 29 in response to the clock signal CLK. In contrast, if the write enable signal 103 is in the low level, the port latch 22 is 20 disabled to hold the latched data.

The port circuit 3 according to the second embodiment attains the data change in units of bits by selecting the change data latched in the port pre-latch circuit 12 on the basis of the mask pattern data 25 held by the mask register circuit 18.

Next, the operation of the port circuit 3 according to the second embodiment of the present invention will be described in detail with reference to timing charts shown in FIGS. 7A to 7G. A case will be described in which the port latch circuit 12 initially holds the data of “1100B” and the data of the bit 0 is changed to “1” in the terminal group 16.

In order to change the data of the bit 0 to “1”, the CPU 1 outputs “1110” as the mask pattern data onto the upper bit portion of the data bus 5 and “1111” as the change data to the lower bit portion thereof while outputting the write signal 100. Thus, “1110111B” is outputted onto the data bus 5. The change data may be any data as long as the bit 0 of the change data takes “1”, and “0001” may be used. However, it is preferable to set the change data to “1111” when the data is changed to “1” and set the change data to “0000” when the data is changed to “0” so as to deal with a case that a bit of the change data may be in another bit position (including a case of a plurality of bit positions). It is therefore becomes possible to change the data in units of bits without requiring a complicated setting.

When the write signal 100 is outputted from the CPU 1, the control circuit 30 outputs the write enable signal 101 to the port pre-latch circuit 10 and the mask register circuit 18. The data on the data bus 5 is supplied to the port pre-latch circuit 10 and the mask register circuit 18 in response to the clock signal CLK during a period of the write enable signal 101 in the high level. The port pre-latch circuit 10 receives the data of “1111B” on the lower 4-bit portion of the data bus 5, whereas the mask register circuit 18 receives the data of “1110B” on the upper 4-bit portion of the data bus 5.

The enable register 17 outputs the write enable signal 103 in the high level during a period of the write enable signal 101 in the high level in synchronization with the clock signal. That is, the enable register 17 outputs the write enable signal 103 in synchronization with a clock of the clock signal CLK subsequent to the clock when the data has been latched in the port pre-latch circuit 10 and the mask register circuit 18.

The port latch circuit 12 latches the data outputted from the selecting circuit 19 in accordance with the write enable signal 103 in a high level. In this example, only the selector 29 corresponding to the bit 0 selects the output data “1” from the corresponding port pre-latch 20 on the basis of the output data of “1110B” from the mask register circuit 18 to output to the port latch 22, whereas the selectors 29 corresponding to the bits 1 to 3 select the output data of the corresponding port latches 22 to output to the port latches 22. Therefore, the port latch circuit 12 includes a data changed only in the port latch 22 corresponding to the bit 0 and the previous data maintained in the remaining port latches 22. Thus, the data held by the port latch circuit 12 is changed from “1100” to “1101”. The data “1101” held by the port latch circuit 12 is outputted to the terminal group 16 via the output control circuit 14.

As described above, the mask pattern data and the change data are supplied at the same timing in the port circuit 3 according to the second embodiment. Therefore, the mask pattern data indicating bits to be changed and the change data are both supplied to the port latch circuit 12 without breaking a corresponding relationship therebetween, so that the operation consistency is maintained. The port circuit 3 according to the present invention also makes it possible to change the data in units of bits without receiving effects of the interruption.

Furthermore, the port circuit 3 according to the present embodiment is provided with the configuration using the selecting circuit, to allow an easy improvement from the conventional technique.

Although the present invention has been described above referring to preferred embodiments, no limitation with respect to specific embodiments disclosed herein is intended, and various changes and modifications can be made herein without departing from a scope of the invention.

What is claimed is:

1. An output port circuit comprising:
a plurality of output buffers;
a plurality of first holding circuits configured to hold output data to be outputted to said plurality of output buffers;
a plurality of second holding circuits configured to hold output data to be outputted to said plurality of first holding circuits; and
a plurality of third holding circuits configured to hold bit pattern data for individually setting whether the output data of said plurality of second holding circuits are latched by said plurality of first holding circuits,
wherein data input to said plurality of second holding circuits and data input to said plurality of third holding circuits are controlled at a same timing.

2. The output port circuit according to claim 1, wherein said plurality of second holding circuits and said plurality of third holding circuits operate in synchronization with a same clock signal,
said plurality of second holding circuits latch the output data in response to a first write enable signal which is generated based on a write signal from an operation processing unit, and
said plurality of third holding circuits latch the bit pattern data in response to the first write enable signal.

3. The output port circuit according to claim 2, wherein said plurality of second holding circuits hold data on a plurality of first signal lines of a data bus in response to said first write enable signal, and
said plurality of third holding circuits latch data on plurality of second signal lines of said data bus, which are different from said plurality of first signal lines, in response to the first write enable signal.

4. The output port circuit according to claim 3, wherein said data bus has a bus width of at least twice of the number of input/output terminals.

5. The output port circuit according to claim 1, wherein data input to said plurality of first holding circuits is controlled based on said bit pattern data held by said plurality of third holding circuits.

6. The output port circuit according to claim 1, further comprising:
a selecting circuit configured to select one of a plurality of first data held by said plurality of first holding circuits and a plurality of second data held by said plurality of second holding circuits in units of bits based on the bit pattern data held by said plurality of third holding circuits,
wherein said plurality of first holding circuits hold the output data from said selecting circuit.

7. The output port circuit according to claim 6, further comprising:
a fourth holding circuit configured to control the data input to said plurality of first holding circuits,
said fourth holding circuit outputs a second write enable signal in synchronization with a clock of a clock signal next to input of a first write enable signal, and
wherein said plurality of first holding circuits hold an output data from said selecting circuit in response to the second write enable signal.

8. A microcomputer comprising:
an output port circuit comprising:
a plurality of output buffers,
a plurality of first holding circuits configured to hold output data to be outputted to said plurality of output buffers,
a plurality of second holding circuits configured to hold output data to be outputted to said plurality of first holding circuits, and
a plurality of third holding circuits configured to hold bit pattern data for individually setting whether the output data of said plurality of second holding circuits are latched by said plurality of first holding circuits,
wherein data input to said plurality of second holding circuits and data input to said plurality of third holding circuits are controlled at a same timing;
a data bus connected with said output port circuit;
a memory; and
an operation processing circuit configured to output a write signal based on an instruction code stored in said memory,
wherein said operation processing circuit outputs data on said data bus, and
said output port circuit holds the data on said data bus in response to the write signal to output to an external unit.

9. The microcomputer according to claim 8, wherein said plurality of second holding circuits and said plurality of third holding circuits operate in synchronization with a same clock signal,
said plurality of second holding circuits latch the output data in response to a first write enable signal which is generated based on a write signal from an operation processing unit, and
said plurality of third holding circuits latch the bit pattern data in response to the first write enable signal.

10. The microcomputer according to claim 9, wherein said plurality of second holding circuits hold data on a plurality of first signal lines of said data bus in response to said first write enable signal, and said plurality of third holding circuits latch data on plurality of second signal lines of said data bus, which are different from said plurality of first signal lines, in response to the first write enable signal.

11. The microcomputer according to claim 10, wherein said data bus has a bus width of at least twice of the number of input/output terminals.

12. The microcomputer according to claim 8, wherein data input to said plurality of first holding circuits is controlled based on said bit pattern data held by said plurality of third holding circuits.

13. The microcomputer according to claim 8, wherein said output port circuit further comprises:
a selecting circuit configured to select one of a plurality of first data held by said plurality of first holding circuits and a plurality of second data held by said plurality of second holding circuits in units of bits based on the bit pattern data held by said plurality of third holding circuits,
wherein said plurality of first holding circuits hold the output data from said selecting circuit.

14. The microcomputer according to claim 13, wherein said output port circuit further comprises:
a fourth holding circuit configured to control the data input to said plurality of first holding circuits,
said fourth holding circuit outputs a second write enable signal in synchronization with a clock of a clock signal next to input of a first write enable signal, and
said plurality of first holding circuits hold an output data from said selecting circuit in response to the second write enable signal.

15. A data outputting method comprising:
a plurality of second holding circuits latching and holding output data to be outputted to a plurality of first holding circuits;
a plurality of third holding circuits latching and holding bit pattern data for individually setting whether the output data of said plurality of second holding circuits are latched by a plurality of first holding circuits, at a same timing as said plurality of second holding circuits;
a plurality of first holding circuits holding output data to be outputted to a plurality of output buffers; and
said plurality of output buffers outputting output data held by said plurality of first holding circuits.

16. The data outputting method according to claim 15, wherein said latching and holding output data comprises:
said plurality of second holding circuits holding data on a plurality of first signal lines of a data bus in response to a first write enable signal, and
said latching and holding bit pattern data comprises:
said plurality of third holding circuits latching data on plurality of second signal lines of said data bus, which are different from said plurality of first signal lines, in response to the first write enable signal.

17. The data outputting method according to claim 15, wherein said holding output data to be outputted to a plurality of output buffers comprises:
a portion of said plurality of first holding circuits, which is permitted based on the bit pattern data, acquiring data from said plurality of second holding circuits.

18. The data outputting method according to claim 15, wherein said holding output data to be outputted to a plurality of output buffers comprises:
a selecting circuit selecting one of a plurality of first data held by said plurality of first holding circuits and a plurality of second data held by said plurality of second holding circuits in units of bits based on the bit pattern data held by said plurality of third holding circuits; and
said plurality of first holding circuits holding as the output data, data outputted from said selecting circuit.
